(19) United States
(12) Patent Application Publication
(10) Pub. No.: US 2023/0290623 A1
(43) Pub. Date: Sep. 14, 2023

(54) PLASMA PROCESSING DEVICE AND PLASMA PROCESSING METHOD

(71) Applicant: ULVAC, INC., Chigasaki-shi (JP)

(72) Inventors: Kenta Doi, Chigasaki-shi (JP); Toshiyuki Nakamura, Chigasaki-shi (JP)

(21) Appl. No.: 18/118,559

(22) Filed: Mar. 7, 2023

(30) Foreign Application Priority Data
Mar. 10, 2022 (JP) 2022-036720

(51) Int. Cl. H01J 37/32

(52) U.S. Cl. CPC H01J 37/32935; H01J 37/32146; H01J 2237/24564; H01J 2237/334; H01J 37/32192; H01J 2237/24585

(57) ABSTRACT

A method for processing a subject with plasma includes repeatedly outputting first pulses from a pulse generator to a first high-frequency power supply, intermittently outputting first high-frequency power from the first high-frequency power supply to a first electrode based on the first pulses to generate the plasma, detecting start of plasma generation caused by a present first pulse with a detector, calculating a delay period, being from rise of the present first pulse until the detector detects start of plasma generation, repeatedly outputting second pulses from the pulse generator to a second high-frequency power supply based on time at which the delay period has elapsed from rise of a first pulse output after the delay period is calculated, and outputting second high-frequency power from the second high-frequency power supply to a second electrode based on the second pulses to draw ions from the plasma to the subject.

### CLAIM OF PRIORITY

This application claims the benefit of priority under 35 U.S.C. § 119 to Japanese Patent Application No. 2022-036720, filed on Mar. 10, 2022, which is incorporated by reference herein in its entirety.

### 1. FIELD

The following description relates to a plasma processing device and a plasma processing method.

### 2. DESCRIPTION OF RELATED ART

An etching device, which is an example of a plasma processing device, includes a first electrode for generating plasma and a second electrode for drawing ions from the plasma to a processing subject. The etching device further includes a first high frequency power supply that outputs high frequency power to the first electrode, a second high frequency power supply that outputs high frequency power to the second electrode, and a pulse generator that controls outputting timings of the first high frequency power supply and the second high frequency power supply. The first high frequency power supply intermittently outputs high frequency power to the first electrode based on first pulses that are output from the pulse generator. This intermittently generates plasma. The second high frequency power supply intermittently outputs high frequency power to the second electrode based on second pulses that are output from the pulse generator. This draws ions from the plasma to the processing subject. The pulse generator uses the first pulses to control the timing of outputting power from the first high frequency power supply and uses the second pulses to control the timing of outputting power from the second high frequency power supply (for example, refer to Japanese Laid-Open Patent Publication No. 2014-107363).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

It is preferred that the timing of outputting high frequency power from the second high frequency power supply to the second electrode be set in accordance with the timing for generating plasma so that ions are appropriately drawn from the plasma. The length of time from when the first pulse is output from the pulse generator to when plasma is generated varies depending on various processing conditions such as the type of gas, the pressure of gas, and the amount of high frequency power. Even when the processing conditions are set the same, the length of time from when the first pulse is output to when plasma is generated also varies due to a slight difference in the atmosphere in a chamber in which plasma is generated. Hence, the second high frequency power supply may output power to the second electrode at a timing deviated from the intended timing with respect to when plasma is generated. Such a phenomenon is not limited to an etching device and is common to other plasma processing devices that intermittently output power from a first high frequency power supply and intermittently output power from a second high frequency power supply, such as a sputtering device and a chemical vapor deposition (CVD) device.

An aspect of the present disclosure is a plasma processing method for processing a subject with plasma. The plasma processing method includes repeatedly outputting first pulses from a pulse generator to a first high frequency power supply, intermittently outputting first high frequency power from the first high frequency power supply to a first electrode based on the first pulses to generate the plasma, detecting a start of generation of the plasma caused by a present one of the first pulses with a detector, calculating a delay period, the delay period being from a rise of the present one of the first pulses until the detector detects the start of generation of the plasma, repeatedly outputting second pulses from the pulse generator to a second high frequency power supply based on a point in time at which the delay period has elapsed from a rise of one of the first pulses that is output after the delay period is calculated, and outputting second high frequency power from the second high frequency power supply to a second electrode based on the second pulses to draw ions from the plasma to the subject.

With this method, even when there is a delay between an output of the first pulse and a start of generation of the plasma that depends on the processing condition and the processing environment of the plasma, the second high frequency power is output based on the point in time at which the plasma starts to be generated.

An aspect of the present disclosure is a plasma processing device that processes a subject with plasma. The plasma processing device includes a first high frequency power supply that outputs first high frequency power to a first electrode to generate the plasma, a second high frequency power supply that outputs second high frequency power to a second electrode to draw ions from the plasma to the subject, a pulse generator that repeatedly outputs first pulses and repeatedly outputs second pulses, the first pulses causing the first high frequency power supply to intermittently output the first high frequency power, and the second pulses causing the second high frequency power supply to intermittently output the second high frequency power, and a detector that detects a start of generation of the plasma. The pulse generator includes a computing unit that calculates a delay period, the delay period being from a rise of a present one of the first pulses until the detector detects the start of generation of the plasma that is caused by the present one of the first pulses. The pulse generator outputs the second pulses based on a point in time at which the delay period has elapsed from a rise of one of the first pulses that is output after the delay period is calculated.

With the method and the device described above, even when there is a delay between an output of the first pulse and a start of generation of the plasma that depends on the processing condition and the processing environment of the plasma, the second high frequency power is output based on the point in time at which the plasma starts to be generated.

Other features and aspects will be apparent from the following detailed description, the drawings, and the claims.

### BRIEF DESCRIPTION OF THE DRAWINGS

FIG. 1 is a schematic diagram illustrating the structure of an etching device in a first embodiment.

FIG. 2 is a block diagram illustrating the structure of a pulse generator in the first embodiment.

FIG. 3 is a flowchart illustrating the steps of starting a plasma process in the first embodiment.

FIG. 4 is a chart illustrating the relationship of first pulse, first high frequency power, and plasma density in the first embodiment.

FIG. 5 is a chart illustrating the relationship of first pulse, plasma density, second pulse, and second high frequency power in the first embodiment.

FIG. 6 is a schematic diagram illustrating the structure of an etching device in a second embodiment.

FIG. 7 is a chart illustrating the relationship of first pulse, first high frequency power, plasma density, and reflected power in the second embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

### First Embodiment

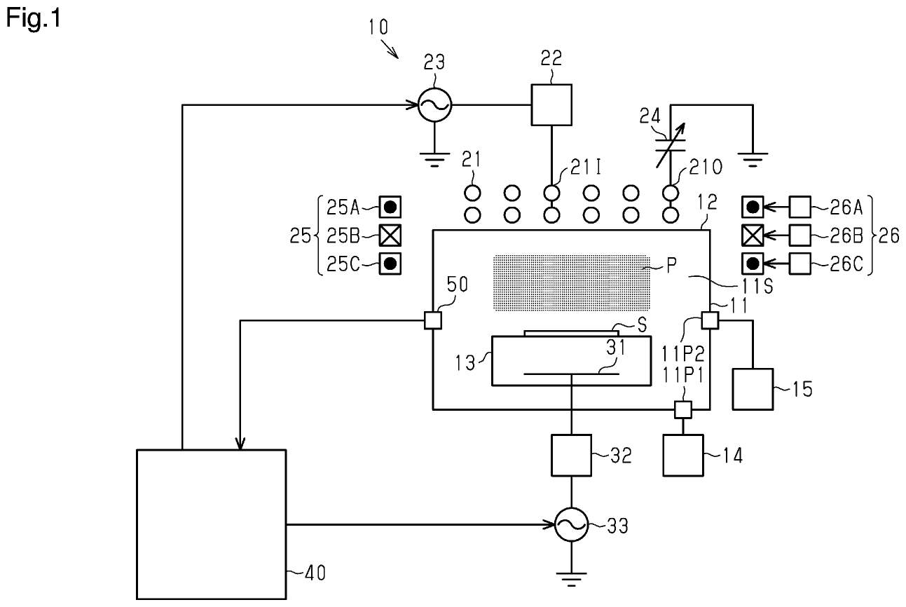

A first embodiment of a plasma processing device and a plasma processing method will be described below with reference to FIGS. 1 to 5.

Etching Device

FIG. 1 illustrates an etching device 10, which is an example of a plasma processing device. The etching device 10 includes a cylindrical chamber body 11 having a closed end and an upper opening and a dielectric window 12 sealing the upper opening of the chamber body 11. The chamber body 11 and the dielectric window 12 define a chamber cavity 11S. The chamber cavity 11S accommodates a stage 13. The stage 13 retains a substrate S, which is an example of a subject that is etched in a plasma process.

The chamber body 11 is a metal structural body formed from aluminum or the like. The dielectric window 12 includes a base member formed from quartz and a coating formed from alumina or the like and formed of a sprayed ceramic film. The coating covers a surface of the base member located at the side of the chamber cavity 11S.

The chamber body 11 includes a discharge port 11P1 and a gas supply port 11P2. The discharge port 11P1 is connected to a discharging unit 14 that discharges fluid from the chamber cavity 11S. In an example, the discharging unit 14 includes a pump of various types or a pressure adjusting valve that adjusts the pressure of the chamber cavity 11S. The gas supply port 11P2 is connected to a gas supply unit 15 that sends etching gas to the chamber cavity 11S. In an example, the gas supply unit 15 includes a mass flow controller that supplies the etching gas. Examples of the etching gas include halogen gases such as a fluorine-containing gas, a chlorine-containing gas, and a boron-containing gas.

An inductively coupled plasma (ICP) antenna 21, which is an example of a first electrode, is disposed at a side of the dielectric window 12 opposite from the chamber cavity 11S. In an example, the ICP antenna 21 includes two layers of spiral coils. In each layer, the spiral coil is wound two and a half turns in a circumferential direction of the substrate S. The ICP antenna 21 includes an input end 211, which is an end located toward the center of the spiral shape, and an output end 210, which is an end located at an outer side of the spiral shape.

The input end 211 of the ICP antenna 21 is connected to an antenna power supply 23 by an antenna matching unit 22. The antenna power supply 23 is an example of a first high frequency power supply. The antenna power supply 23 outputs first high frequency power. In an example, the first high frequency power is 13.56 MHz.

The antenna matching unit 22 is an example of a matching circuit. The antenna matching unit 22 is configured to match an output impedance of the antenna power supply 23 with an input impedance of a load that receives the first high frequency power, thereby limiting reflected power caused by the load. In an example, the antenna matching unit 22 includes a variable capacitor and a fixed capacitor.

The output end 210 of the ICP antenna 21 is connected to ground by a capacitor 24. The capacitor 24 is configured to increase the amplitude of electric potential at the output end 210 of the ICP antenna 21 as compared to a structure that directly connects the output end 210 is to ground potential. The capacitor 24 adjusts the distribution of voltage applied to the ICP antenna 21 so as to minimize non-uniformity of the plasma density that occurs when a high frequency voltage is applied to the ICP antenna 21 and plasma Pin the chamber cavity 11S is coupled to the ICP antenna 21 through capacitive coupling. The capacitor 24 may have a capacitance of, for example, greater than or equal to 10 pF and less than or equal to 1000 pF.

A magnetic field coil 25 is disposed around the circumference of the dielectric window 12 to form a magnetic neutral line in the chamber cavity 11S. The magnetic field coil 25 includes an upper coil portion 25A, a middle coil portion 25B, and a lower coil portion 25C.

The three coil portions of the magnetic field coil 25 are separately connected to a current source 26 that supplies current to form the magnetic neutral line. The upper coil portion 25A is connected to an upper current source 26A. The middle coil portion 25B is connected to a middle current source 26B. The lower coil portion 25C is connected to a lower current source 26C. The upper current source 26A and the lower current source 26C supply a current in the same direction to the upper coil portion 25A and the lower coil portion 25C, respectively. The middle current source 26B supplies a current to the middle coil portion 25B in a direction opposite to the direction of the currents supplied by the current sources 26A and 26C. The direction and the amount of current supplied from each of the current sources 26A, 26B, and 26C are set so that the magnetic neutral line is formed in the chamber cavity 11S.

The stage 13 incorporates a bias electrode 31. The bias electrode 31 is an example of a second electrode. The bias electrode 31 is connected to a bias power supply 33 by a bias matching unit 32. The bias power supply 33 is an example of a second high frequency power supply. The bias power supply 33 outputs the second high frequency power. The second high frequency power is, for example, 12.5 MHz, 2 MHz, or 400 kHz. The bias matching unit 32 is configured to match an output impedance of the bias power supply 33 with an input impedance of a load that receives the second high frequency power, thereby limiting reflected power caused by the load.

When the chamber cavity 11S is supplied with an etching gas and the first high frequency power is supplied to the ICP antenna 21, the plasma P is generated in the chamber cavity 11S. In an example, the plasma P includes inductively coupled plasma. When the plasma P is generated in the chamber cavity 11S and the second high frequency power is supplied to the bias electrode 31, ions are drawn from the plasma P to the substrate S.

The etching device 10 includes a pulse generator 40 and a light receiving element 50. The pulse generator 40 outputs separate pulse signals to the antenna power supply 23 and the bias power supply 33 to control the antenna power supply 23 and the bias power supply 33. The light receiving element 50 is an example of a detector that detects a start of generation of the plasma P in the chamber cavity 11S based on light emission of the plasma P and notifies the pulse generator 40 that generation of the plasma P has started. In an example, the light receiving element 50 includes a photodiode that outputs an electric signal when the plasma P starts to be generated and starts to emit light.

In an example, the etching device 10 generates the plasma P under the following etching condition. The etching condition is not limited to that described below.

Etching Condition
Substrate: sapphire substrate
First High Frequency Power: 2100 W
Frequency of First High Frequency Power: 13.56 MHz
Second High Frequency Power: 1000 W
Frequency of Second High Frequency Power: 12.5 MHz
Etching Gas: BCl₃
Etching Gas Flow Rate: 150 sccm

Pulse Generator

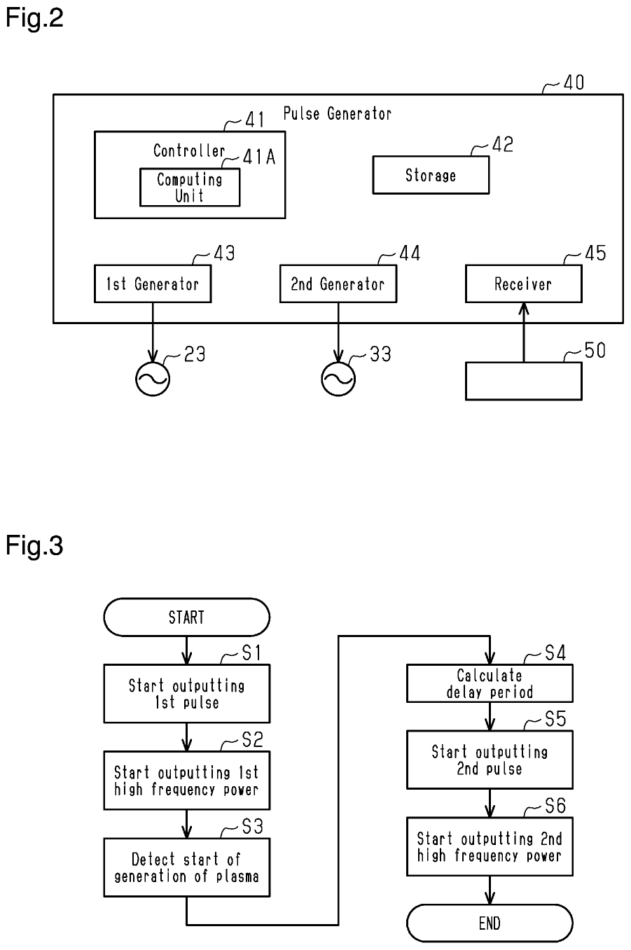

As illustrated in FIG. 2, the pulse generator 40 includes a controller 41, storage 42, a first generator 43, a second generator 44, and a receiver 45. The controller 41 controls each component of the pulse generator 40. In an example, the controller 41 is a central processing unit (CPU). The storage 42 stores programs and processing conditions for controlling each component of the pulse generator 40 with the controller 41.

The first generator 43 outputs a first pulse for controlling the antenna power supply 23. The antenna power supply 23 outputs the first high frequency power based on the first pulse. The second generator 44 outputs a second pulse for controlling the bias power supply 33. The bias power supply 33 outputs the second high frequency power based on the second pulse. The second generator 44 outputs the second pulse after a predetermined period elapses from when the first generator 43 outputs the first pulse.

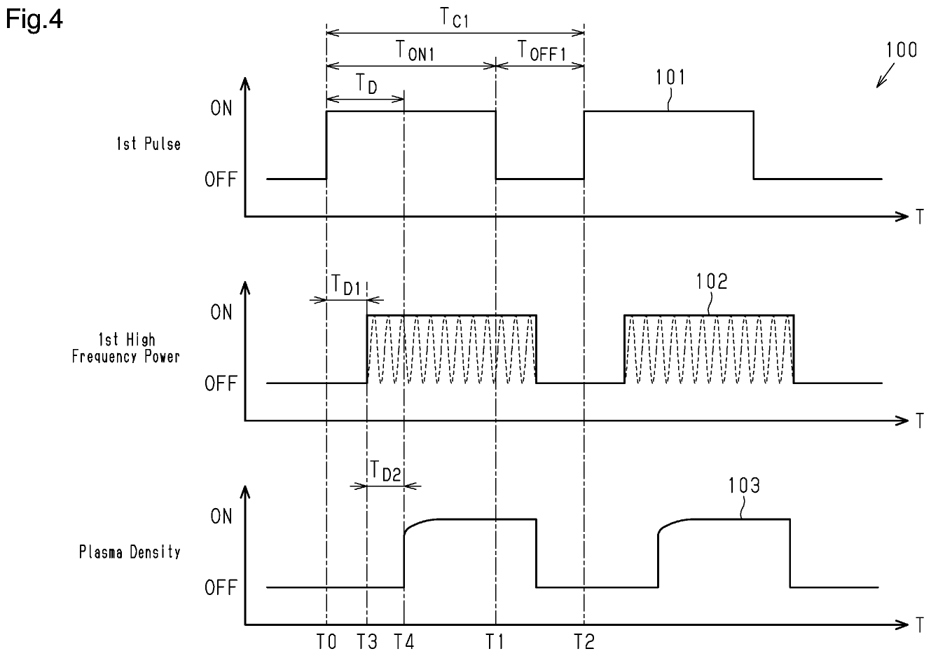

When the light receiving element 50 detects a start of generation of the plasma P in the chamber cavity 11S, the receiver 45 receives an electrical signal output from the light receiving element 50 as a detection signal. The controller 41 includes a computing unit 41A that calculates a delay period T_{D} (refer to FIG. 4), which is a length of time taken from a rise of the present first pulse until the light receiving element 50 detects a start of generation of the plasma P by the present first pulse.

Plasma Process Starting Procedure

As illustrated in FIG. 3, the procedure for starting a plasma process includes steps S1 to S6. In step S1, the controller 41 causes the first generator 43 to execute a process for starting to output the first pulse. In step S2, the antenna power supply 23 starts to output the first high frequency power based on a rise of the first pulse that is output from the first generator 43. The output first high frequency power generates the plasma P in the chamber cavity 11S. In step S3, the light receiving element 50 detects a start of generation of the plasma P and outputs a detection signal. The detection signal is received by the receiver 45 of the pulse generator 40.

The relationship of the first pulse, the first high frequency power, and the plasma density in steps S1 to S3 will be described with reference to FIG. 4.

In graph 100 illustrated in FIG. 4, a curve 101 illustrates the first pulse that is repeatedly output. The first pulse is a square wave that is repeatedly output at a predetermined first frequency. The first frequency is, for example, greater than or equal to 10 Hz and less than or equal to 50 kHz. The first pulse is repeatedly output in a cycle of a predetermined first period T_{C1} so that a first on duration T_{ON1}, in which the pulse signal is on, alternates with a first off duration T_{OFF1}, in which the pulse signal is off, at predetermined intervals. The first pulse rises at time point TO to start the first on duration T_{ON1}. Then, the first pulse falls at time point T1. Consequently, the first pulse is switched from the first on duration T_{ON1} to the first off duration T_{OFF1}. At time point T2, the first pulse again starts the first on duration T_{ON1}. In the example illustrated in FIG. 4, the length of time from time point T0 to time point T2 corresponds to the first period T_{C1}. The ratio of the first on duration T_{ON1} to the first period T_{C1} is referred to as a first duty ratio and is, for example, greater than or equal to 10% and less than or equal to 90%.

In graph 100, a curve 102 schematically illustrates timings of outputting the first high frequency power. The antenna power supply 23 outputs the first high frequency power for a length of time corresponding to the first on duration T_{ON1} of the first pulse. The first high frequency power starts to be output at time point T3. Time point T3 is delayed from time point T0, at which the first pulse is output, by a first output delay period T_{D1}. The first output delay period T_{D1} is a delay due to a control time constant of the antenna power supply 23. The first output delay period T_{D1} is unique to the antenna power supply 23.

In graph 100, a curve 103 illustrates the plasma density. The plasma P starts to be generated at time point T4. Time point T4 is delayed from time point T3, at which the first high frequency power is output, by a plasma generation start delay period T_{D2}. The plasma generation start delay period T_{D2} is a length of time from when the first high frequency power is output to when the plasma P starts to be generated. The sum of the first output delay period T_{D1} and the plasma generation start delay period T_{D2} is referred to as a delay period T_{D}. The plasma P starts to be generated at a point in time when the delay period T_{D} elapses from time point T0, at which the first pulse is output. The plasma P is intermittently generated at an interval corresponding to the first frequency.

The plasma generation start delay period T_{D2} varies depending on the processing condition such as the type of gas, the pressure of gas, and electric power. Even when the processing condition is set the same, the plasma generation start delay period T_{D2} also varies depending on a slight difference in the atmosphere in the chamber in which the plasma P is generated. The plasma generation start delay period T_{D2} may be subtle depending on the processing condition.

In FIG. 3, in step S4, based on a detection signal received by the receiver 45 from the light receiving element 50, the computing unit 41A calculates the delay period T_{D}, which is a length of time taken from time point T0, at which the first pulse rises, to when the light receiving element 50 detects the start of generation of the plasma P. The delay period T_{D} calculated by the computing unit 41A coincides with a period from time point T0, at which the first pulse rises, to time point T4, at which the plasma P starts to be generated. The delay period T_{D} calculated by the computing unit 41A is stored in the storage 42.

Preferably, the process for calculating the delay period T_{D} in step S4 may be executed based on a first pulse that is output after a lapse of a predetermined stabilization period, which is from when the first pulse starts to be output in step S1 to when generation of the plasma P is stabilized. In this case, the delay period T_{D} is calculated when the light receiving element 50 detects light emission of the plasma P generated by a first pulse that is output after a lapse of the stabilization period. The stabilization period is, for example, greater than or equal to one second and less than or equal to five seconds. Calculation of the delay period T_{D} during stable generation of the plasma P decreases the difference in point in time between when the delay period T_{D}, which is calculated from a rise of the first pulse, elapses and when the plasma P starts to be generated.

The delay period T_{D} may be obtained from a single calculation of the time taken from a rise of the first pulse to a start of generation of the plasma P. Alternatively, the delay period T_{D} may be obtained by calculating the time taken from a rise of the first pulse to a start of generation of the plasma P a number of times and obtaining an average value of the calculation results.

In step S4, after the delay period T_{D} is calculated, in step S5, the controller 41 causes the second generator 44 to execute a process for starting to output the second pulse. The second pulse is output so as to rise at any timing based on the point in time at which the delay period T_{D} elapses from the rise of the first pulse. In step S6, the bias power supply 33 starts to output the second high frequency power based on the second pulse output from the second generator 44. The procedure described above starts the plasma process.

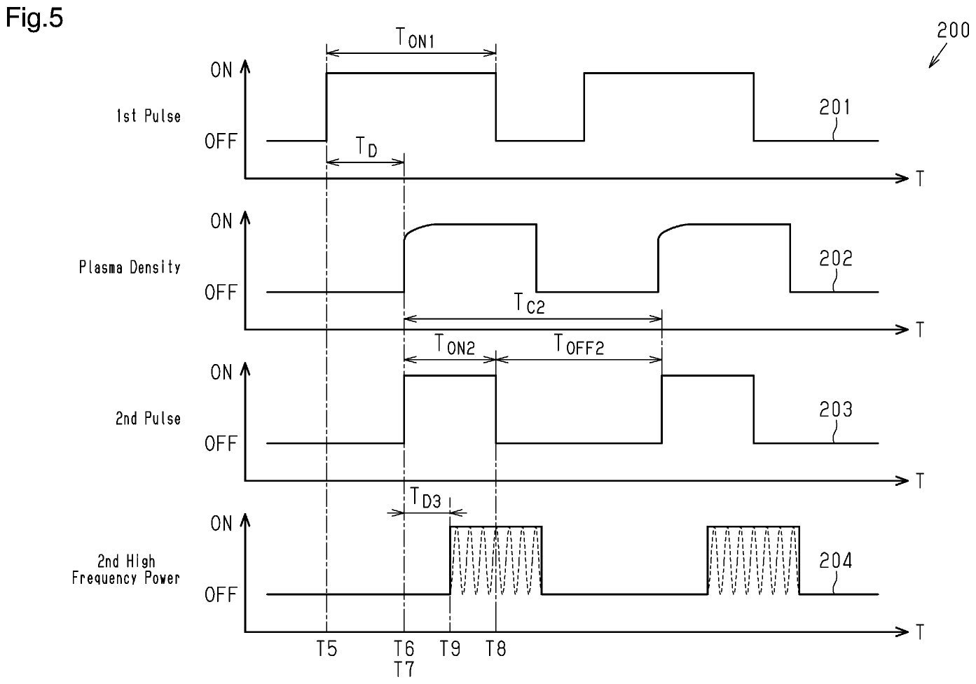

The relationship of the first pulse, the plasma density, the second pulse, and the second high frequency power from step S5 will now be described with reference to FIG. 5.

In graph 200 illustrated in FIG. 5, a curve 201 illustrates the first pulse that is repeatedly output. A curve 202 illustrates the plasma density. From step S5, the first pulse rises at time point T5 to start the first on duration T_{ON1}. The plasma P starts to be generated at time point T6, which is delayed from time point T5 by the delay period T_{D}. The shape of the curve 201 is substantially the same as the shape of the curve 101 illustrated in FIG. 4 The shape of the curve 202 is substantially the same as the shape of the curve 102 illustrated in FIG. 4. Time point T5 comes after the delay period T_{D} is calculated in step S4.

In graph 200, a curve 203 illustrates the second pulse that is repeatedly output. The second pulse is a square wave that is repeatedly output at a predetermined second frequency. The second frequency is equal to the first frequency or a value obtained by dividing the first frequency by a natural number that is greater than or equal to two. In other words, the value of the first frequency is obtained by multiplying the second frequency and the natural number. In FIG. 5, the second frequency is equal to the first frequency. The second pulse is repeatedly output in a cycle of a predetermined second period T_{C2} so that the second on duration T_{ON1}, in which the pulse signal is on, alternates with a second off duration T_{OFF2}, in which the pulse signal is off. The ratio of the second on duration T_{ON1} to the second period T_{C2} is referred to as a second duty ratio. When the first frequency is equal to the second frequency, the second duty ratio is, for example, less than or equal to the first duty ratio. In an example, the second duty ratio is greater than or equal to 10% and less than or equal to 90%. When the second frequency is less than the first frequency, the second duty ratio is less than the first duty ratio.

The second pulse includes a pulse wave that rises at time point T7, starting the second on duration T_{ON2}, and then falls at time point T8. This switches the second pulse from the second on duration T_{ON2} to the second off duration T_{OFF2}. Time point T7 is set based on the point in time when the delay period T_{D} elapses from time point T5, at which the first pulse rises. The point in time when the delay period T_{D} elapses from time point T5 substantially coincides with time point T6, at which the plasma P starts to be generated. In FIG. 5, time point T7 substantially coincides with time point T6. However, time point T7 may be delayed from time point T6 by a predetermined length of time that does not exceed the second period T_{C2}.

In graph 200, a curve 204 schematically illustrates timings of outputting the second high frequency power. The bias power supply 33 outputs the second high frequency power for a length of time corresponding to the second on duration T_{ON2} of the second pulse. The second high frequency power starts to be output at time point T9. Time point T9 is delayed from time point T7, at which the second pulse is output, by a second output delay period T_{D3}. The second output delay period T_{D3} is a delay due to a control time constant of the bias power supply 33. The second output delay period T_{D3} is unique to the bias power supply 33. The procedure described above outputs the second high frequency power based on the timing of a start of generation of the plasma P.

When time point T7 is set to a time delayed from time point T6 by a predetermined length of time, time point T7 may be set taking into consideration the second output delay period T_{D3}, which is unique to the bias power supply 33.

Preferably, the calculation of the delay period T_{D} in steps S1 to S4 is executed whenever the plasma generation start delay period T_{D2} greatly varies due to changes in the processing condition such as the type of gas, the pressure of gas, and power and changes in the processing environment resulting from a long-time use. In an example, when the delay period T_{D} is calculated to start the plasma process on a substrate S, which is a processing subject, it is preferred that the delay period T_{D} be calculated again when starting the plasma process on another substrate S. Even when the processing environment changes in accordance with a long-time use or replacement of the substrate S, the above configuration reduces variations in the difference between the point in time when the delay period T_{D} elapses from a rise of the first pulse and the point in time when the plasma P starts to be generated.

### Effects of First Embodiment

The first embodiment has the following effects.
(1-1) There may be a delay between an output of the first pulse and a start of generation of the plasma P that depends on the processing condition and the processing environment of the plasma P. Even in such a case, the second high frequency power is output based on the point in time at which the plasma P starts to be generated.
(1-2) The light receiving element 50, which is a photodiode or the like, is used as the detector. Thus, a start of generation of the plasma P is appropriately detected by the photoelectric effect. This increases the responsiveness to a start of generation of the plasma P, thereby further accurately calculating the delay period T_{D}.
(1-3) The delay period T_{D} may be calculated based on a first pulse that is output after a lapse of the stabilization period, which is from when the first pulse starts to be output (i.e., the first pulse is output for the first time) to when the generation of plasma is stabilized. When the first pulse after a lapse of the stabilization period is used to calculate the delay period T_{D}, the delay period T_{D} is further accurately calculated. Ultimately, this increases the reproducibility of the effect produced by the use of the delay period T_{D}.
(1-4) Whenever the substrate S (subject) is changed, the delay period T_{D} may be calculated. This reduces variations among subjects in the difference between the point in time when the delay period T_{D} elapses from a rise of the first pulse and the point in time when the plasma P starts to be generated even when replacement of the substrate S changes the processing environment.

### Modified Examples of First Embodiment

The first embodiment may be modified as follows.

The light receiving element 50 is not limited to a photodiode and may have any structure that detects a start of generation of the plasma P. In an example, the light receiving element 50 may include a phototransistor. In another example, the light receiving element 50 may include a photoresistor, the electric resistance of which changes in accordance with light emission of the plasma P. Instead of using the light receiving element 50, the detector may use a mechanism that detects heat that is produced in accordance with light emission of the plasma P.

### Second Embodiment

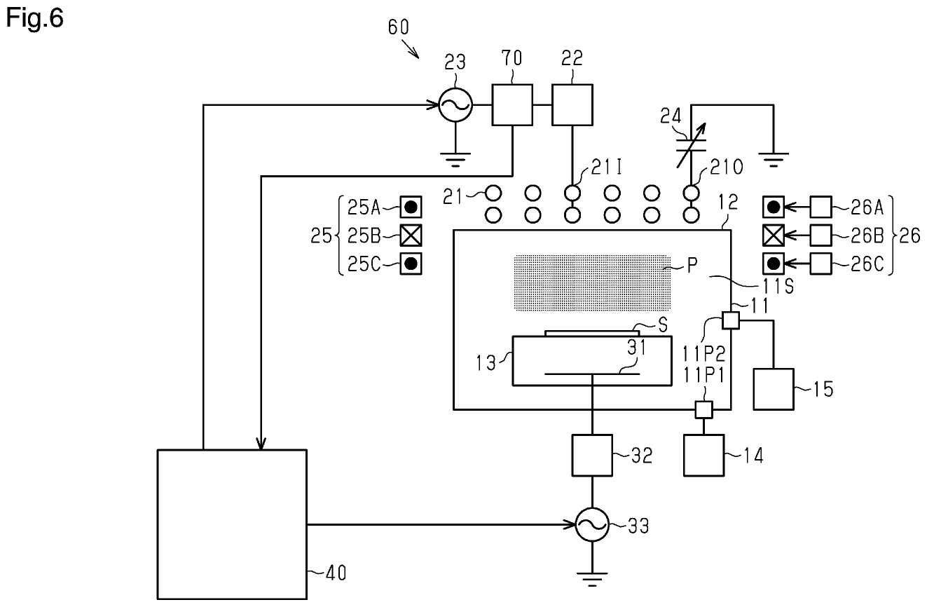

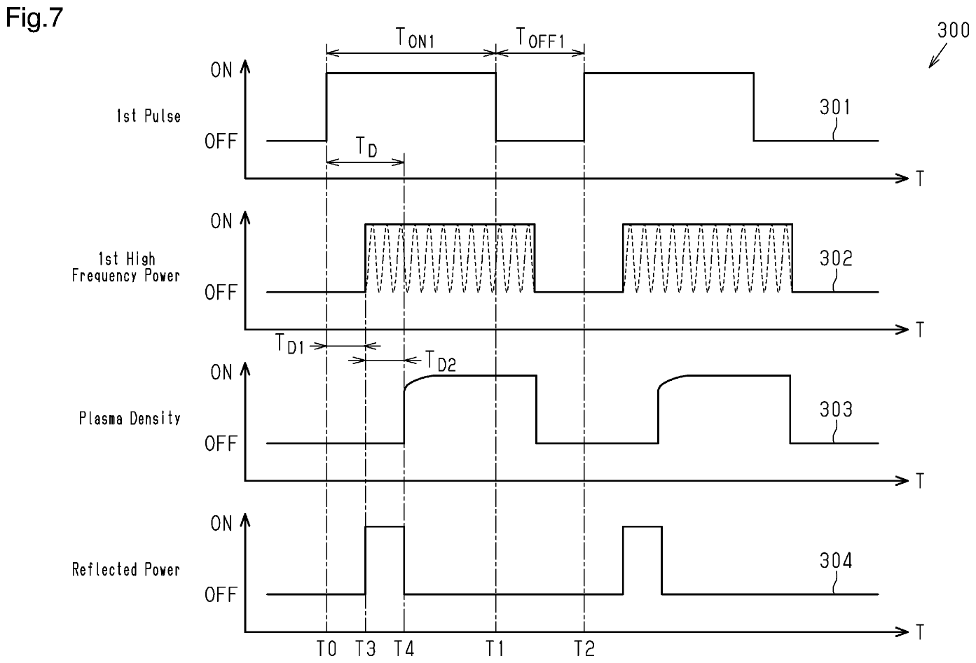

A second embodiment of a plasma processing device and a plasma processing method will be described below with reference to FIGS. 6 and 7.

FIG. 6 illustrates an etching device 60, which is an example of a plasma processing device. The etching device 60 does not include the light receiving element 50 instead includes a directional coupler 70 disposed between the antenna matching unit 22 and the antenna power supply 23. The directional coupler 70 detects the level of reflected power produced by the first high frequency power output from the antenna power supply 23.

In the second embodiment, in an example, the antenna matching unit 22 includes a fixed capacitor. In the second embodiment, the matching point of the antenna matching unit 22 is set in advance so that reflected power will be decreased in accordance with a start of generation of the plasma P.

The directional coupler 70 is an example of a detector that detects a start of generation of the plasma P. The directional coupler 70 detects a decrease in the reflected power, which occurs when the plasma P starts to be generated, and outputs an electrical signal. The electrical signal is received by the receiver 45 as a detection signal. In other words, the reflected power that is produced in accordance with an output of the first high frequency power is decreased in accordance with a start of generation of the plasma P. Thus, the directional coupler 70 detects the start of generation of the plasma P based on a decrease in reflected power.

The relationship of the first pulse, the first high frequency power, the plasma density, and the reflected power in steps S1 to S3 will be described with reference to FIG. 7.

In graph 300 illustrated in FIG. 7, a curve 301 illustrates the first pulse that is repeatedly output. The shape of the curve 301 is the same as the shape of the curve 101 illustrated in FIG. 4. The first pulse rises at time point T0 to start the first on duration T_{ON1}. Then, the first pulse falls at time point T1. Consequently, the first pulse is switched from the first on duration T_{ON1} to the first off duration T_{OFF1}. At time point T2, the first pulse again rises and starts first on duration T_{ON1}.

A curve 302 schematically illustrates timings of outputting the first high frequency power. The shape of the curve 302 is the same as the shape of the curve 102 illustrated in FIG. 4. The first high frequency power starts to be output at time point T3. Time point T3 is delayed from time point T0, at which the first pulse is output, by a first output delay period T_{D1}.

A curve 303 illustrates the plasma density. The shape of the curve 303 is the same as the shape of the curve 103 illustrated in FIG. 4. The plasma P starts to be generated at time point T4. Time point T4 is delayed from time point T3, at which the first high frequency power is output, by a plasma generation start delay period T_{D2}. The plasma P starts to be generated at a point in time when the delay period T_{D} elapses from time point T0, at which the first pulse is output.

In graph 300, a curve 304 illustrates the level of reflected power detected by the directional coupler 70. When the first high frequency power is output at time point T3, until the plasma P starts to be generated, reflected power is produced due to a difference between the output impedance of the antenna power supply 23 and the input impedance of the load that receives the first high frequency power. At time point T4, when the plasma P starts to be generated, the input impedance of the load approaches the output impedance of the antenna power supply 23. This decreases the reflected power. Thus, time point T4, at which the plasma P starts to be produced, coincides with the time at which the reflected power decreases. This allows the directional coupler 70 to detect a start of generation of the plasma P by detecting a decrease in the reflected power.

### Effects of Second Embodiment

The second embodiment has the following effects.
(2-1) The detection of the time at which reflected power is decreased in accordance with a start of generation of the plasma P also produces the above effects (1-1), (1-3), and (1-4).

### Modified Examples of Second Embodiment

The structure of the antenna matching unit 22 is not limited as long as when calculating the delay period T_{D}, time point T4, at which the plasma P starts to be generated, coincides with a point in time at which reflected power decreases. Therefore, the capacitance of a capacitor in the antenna matching unit 22 may be fixed in at least steps S1 to S4. In an example, the capacitor of the antenna matching unit 22 may be controlled so that the capacitance is fixed in steps S1 to S4 and is variable from step S5.

### Modified Examples of First and Second Embodiments

The first and second embodiments may be modified as follows.

If it is assured by a pretest or the like that replacement of the substrate S will not greatly change the delay period T_{D}, the delay period T_{D} does not have to be calculated whenever the substrate S is replaced. In this case, the delay period T_{D} is calculated in the plasma process for one substrate S and then is used in the plasma process for other substrates S.

If the delay period T_{D} is accurately calculated, the calculation of the delay period T_{D} may be started before the stabilization period elapses from when the first pulse starts to be output. In an example, when it is verified in a pretest or the like that a delay period T_{D} calculated before the stabilization period elapses does not greatly differ from a delay period T_{D} calculated after the stabilization period elapses, the delay period T_{D} may be calculated before the stabilization period elapses.

The ICP antenna 21 may include, for example, one layer of a coil or three or more layers of coils.

The plasma processing device is not limited to the etching device 10 and may include, for example, a film formation device that generates a deposition from a film formation gas or a surface processing device that irradiates the surface of a subject with the plasma P.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A plasma processing method for processing a subject with plasma, the plasma processing method comprising:
repeatedly outputting first pulses from a pulse generator to a first high frequency power supply;
intermittently outputting first high frequency power from the first high frequency power supply to a first electrode based on the first pulses to generate the plasma;
detecting a start of generation of the plasma caused by a present one of the first pulses with a detector;
calculating a delay period, the delay period being from a rise of the present one of the first pulses until the detector detects the start of generation of the plasma;
repeatedly outputting second pulses from the pulse generator to a second high frequency power supply based on a point in time at which the delay period has elapsed from a rise of one of the first pulses that is output after the delay period is calculated; and
outputting second high frequency power from the second high frequency power supply to a second electrode based on the second pulses to draw ions from the plasma to the subject.

2. The plasma processing method according to claim 1, wherein the detector includes a photodiode that detects a start of light emission of the plasma as the start of generation of the plasma.

3. The plasma processing method according to claim 1, wherein the detector detects the start of generation of the plasma based on a decrease in reflected power that is produced in accordance with an output of the first high frequency power.

4. The plasma processing method according to claim 1, wherein the present one of the first pulses is one of the first pulses that is output after a lapse of a predetermined stabilization period, the predetermined stabilization period being from a start of an output of the first pulses until generation of the plasma is stabilized.

5. The plasma processing method according to claim 1, further comprising:
calculating the delay period whenever the subject is changed.

6. A plasma processing device that processes a subject with plasma, the plasma processing device comprising:
a first high frequency power supply that outputs first high frequency power to a first electrode to generate the plasma;
a second high frequency power supply that outputs second high frequency power to a second electrode to draw ions from the plasma to the subject;
a pulse generator that repeatedly outputs first pulses and repeatedly outputs second pulses, the first pulses causing the first high frequency power supply to intermittently output the first high frequency power, and the second pulses causing the second high frequency power supply to intermittently output the second high frequency power; and
a detector that detects a start of generation of the plasma, wherein
the pulse generator includes a computing unit that calculates a delay period, the delay period being from a rise of a present one of the first pulses until the detector detects the start of generation of the plasma that is caused by the present one of the first pulses, and
the pulse generator outputs the second pulses based on a point in time at which the delay period has elapsed from a rise of one of the first pulses that is output after the delay period is calculated.
